(19) United States
(12) Patent Application Publication
(10) Pub. No.: US 2020/0279947 A1
(43) Pub. Date: Sep. 3, 2020

(54) SILICON CARBIDE SEMICONDUCTOR DEVICE AND METHOD OF MANUFACTURING SILICON CARBIDE SEMICONDUCTOR DEVICE

(71) Applicant: Mitsubishi Electric Corporation, Chiyoda-ku, Tokyo (JP)

(72) Inventor: Fumitoshi YAMAMOTO, Tokyo (JP)

(73) Assignee: Mitsubishi Electric Corporation, Chiyoda-ku, Tokyo (JP)

(21) Appl. No.: 16/651,222

(22) PCT Filed: Nov. 9, 2018
(86) PCT No.: PCT/JP2018/041633

§ 371 Date: Mar. 26, 2020

(30) Foreign Application Priority Data
Nov. 13, 2017 (JP) 2017-218380

(51) Int. Cl. H01L 29/78; H01L 29/16; H01L 29/08; H01L 29/423; H01L 29/66; H01L 21/027; H01L 21/04

(52) U.S. Cl. CPC H01L 29/7816; H01L 29/1608; H01L 29/0865; H01L 29/42364; H01L 29/0882; H01L 21/0273; H01L 21/047; H01L 29/42372; H01L 29/66068

(57) ABSTRACT

A silicon carbide semiconductor device is manufactured without reducing an off-state breakdown voltage. The silicon carbide semiconductor device includes a second diffusion layer of a second conductivity type which is partially formed in a surface layer of a silicon carbide semiconductor layer of a first conductivity type, a third diffusion layer of the second conductivity type which is formed in at least part of a surface layer of the second diffusion layer, and a fourth diffusion layer of the first conductivity type which is partially formed in a surface layer of the third diffusion layer, and the third diffusion layer is formed to be shallower than the second diffusion layer, the fourth diffusion layer is formed inside the third diffusion layer in a cross-sectional view, and the third diffusion layer is asymmetric with respect to the second diffusion layer.

### TECHNICAL FIELD

A technique disclosed in the present specification relates to a silicon carbide semiconductor device and a method of manufacturing the same.

### BACKGROUND ART

In a background-art silicon carbide semiconductor device such as a metal-oxide-semiconductor field-effect transistor, i.e., MOSFET, using a SiC substrate, since a surface of the SiC substrate cannot be easily oxidized, in a marking process, first, a mark having a step shape is formed on the surface of the SiC substrate. Then, in a process until a gate electrode is formed, photolithography using the mark is performed, and in each process step, a diffusion layer is formed by ion implantation.

In the case of using the SiC substrate, implanted ions are hardly diffused by heat treatment. Therefore, if a source region and a back gate region (i.e., a body region) are formed on the basis of the same mark, there is almost no difference between a formation width of the source region and that of the back gate region, and as a result, sometimes an off-state breakdown voltage of the MOSFET in a semiconductor chip decreases.

A method to solve such a problem is disclosed, in which an end portion of an implantation mask is tapered, and after forming a back gate region by ion implantation, a source region is thereby formed inside the back gate region by ion implantation (see, for example, Patent Document 1).

### PRIOR ART DOCUMENTS

### Patent Documents

[Patent Document 1] Japanese Patent Application Laid Open Gazette No. 2004-039744

### SUMMARY

### Problem to be Solved by the Invention

In the case where the source region is formed inside the back gate region by using the above-described method, however, the degree of diffusion varies depending on the angle of the tapered shape at the end portion of the implantation mask and as a result, there arises a case where there is almost no difference between the formation width of the source region and that of the back gate region. In such a case, the off-state breakdown voltage of the silicon carbide semiconductor device disadvantageously decreases.

The technique disclosed in the present specification is intended to solve the above-described problem, and it is an object of the present invention to provide a technique of manufacturing a silicon carbide semiconductor device without reducing an off-state breakdown voltage.

### Means to Solve the Problem

A first aspect of the technique disclosed in the present specification includes a silicon carbide semiconductor layer of a first conductivity type, a second diffusion layer of a second conductivity type which is partially formed in a surface layer of the silicon carbide semiconductor layer, a third diffusion layer of the second conductivity type which is formed in at least part of a surface layer of the second diffusion layer, and a fourth diffusion layer of the first conductivity type which is partially formed in a surface layer of the third diffusion layer, and in the first aspect of the technique, the third diffusion layer is formed to be shallower than the second diffusion layer, the fourth diffusion layer is formed inside the third diffusion layer in a cross-sectional view, and the third diffusion layer is formed at a position asymmetric with respect to the second diffusion layer in a cross-sectional view.

A second aspect of the technique disclosed in the present specification includes forming a second diffusion layer of a second conductivity type by ion implantation partially in a surface layer of a silicon carbide semiconductor layer of a first conductivity type, forming a resist pattern on a surface of the silicon carbide semiconductor layer, forming a third diffusion layer of the second conductivity type by ion rotational implantation in at least part of a surface layer of the second diffusion layer which is exposed from the resist pattern, and forming a fourth diffusion layer of the first conductivity type by ion implantation partially in a surface layer of the third diffusion layer which is exposed from the resist pattern.

### Effects of the Invention

The first aspect of the technique disclosed in the present specification includes a silicon carbide semiconductor layer of a first conductivity type, a second diffusion layer of a second conductivity type which is partially formed in a surface layer of the silicon carbide semiconductor layer, a third diffusion layer of the second conductivity type which is formed in at least part of a surface layer of the second diffusion layer, and a fourth diffusion layer of the first conductivity type which is partially formed in a surface layer of the third diffusion layer, and in the first aspect of the technique, the third diffusion layer is formed to be shallower than the second diffusion layer, the fourth diffusion layer is formed inside the third diffusion layer in a cross-sectional view, and the third diffusion layer is formed at a position asymmetric with respect to the second diffusion layer in a cross-sectional view. According to such a configuration, even in a case, for example, where a formation position of a source region deviates from that of the second diffusion layer and a distance between the source region and the silicon carbide semiconductor layer becomes small, since the distance between the source region and the silicon carbide semiconductor layer is ensured by the third diffusion layer, it is possible to suppress reduction in the off-state breakdown voltage of the silicon carbide semiconductor device. Therefore, the yield is improved.

The second aspect of the technique disclosed in the present specification includes forming a second diffusion layer of a second conductivity type by ion implantation partially in a surface layer of a silicon carbide semiconductor layer of a first conductivity type, forming a resist pattern on a surface of the silicon carbide semiconductor layer, forming a third diffusion layer of the second conductivity type by ion rotational implantation in at least part of a surface layer of the second diffusion layer which is exposed from the resist pattern, and forming a fourth diffusion layer of the first conductivity type by ion implantation partially in a surface layer of the third diffusion layer which is exposed from the resist pattern. According to such a method, even in a case, for example, where a formation position of a source region deviates from that of the second diffusion layer and a distance between the source region and the silicon carbide semiconductor layer becomes small, the distance between the source region and the silicon carbide semiconductor layer is ensured by the third diffusion layer which is formed by the ion rotational implantation using the same resist pattern as that used for forming the source region. Therefore, it is possible to suppress reduction in the off-state breakdown voltage of the silicon carbide semiconductor device.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a plan view showing an exemplary arrangement form of MOSFETs and marks in accordance with a preferred embodiment;

FIG. 2 is a plan view schematically showing an exemplary structure of a silicon carbide semiconductor device in accordance with the preferred embodiment;

FIG. 3 is a cross-sectional view corresponding to the cross section of FIG. 2;

FIG. 4 is a cross-sectional view showing an exemplary process until an epitaxial layer is formed in the silicon carbide semiconductor device in accordance with the preferred embodiment;

FIG. 5 is a cross-sectional view showing an exemplary process until a mark is formed in the silicon carbide semiconductor device in accordance with the preferred embodiment;

FIG. 6 is a cross-sectional view showing an exemplary process until ion implantation is performed to form a drain region in the silicon carbide semiconductor device in accordance with the preferred embodiment;

FIG. 7 is a cross-sectional view showing an exemplary process until the ion implantation is performed to form a back gate region in the silicon carbide semiconductor device in accordance with the preferred embodiment;

FIG. 8 is a cross-sectional view showing an exemplary process until the ion implantation is performed to form a P-type diffusion layer in the silicon carbide semiconductor device in accordance with the preferred embodiment;

FIG. 9 is a cross-sectional view showing an exemplary structure in a case where a position of a pattern deviates from a recessed portion serving as a mark when photolithography is performed;

FIG. 10 is a cross-sectional view used for explaining the principle of off-state breakdown voltage in the silicon carbide semiconductor device in accordance with the preferred embodiment;

FIG. 11 is a cross-sectional view showing an exemplary structure in a case where ions are rotationally implanted at an angle of more than 45 degrees;

FIG. 12 is a cross-sectional view showing an exemplary structure in a case where ions are rotationally implanted at an angle of not more than 45 degrees;

FIG. 13 is a cross-sectional view in a case where the angle at an end portion of a resist used for formation of the P-type diffusion layer and a source region is 30 degrees;

FIG. 14 is a cross-sectional view in a case where the angle at the end portion of the resist used for formation of the P-type diffusion layer and the source region is 45 degrees;

FIG. 15 is a cross-sectional view in a case where the angle at the end portion of the resist used for formation of the P-type diffusion layer and the source region is 80 degrees;

FIG. 16 is a cross-sectional view showing an exemplary process until the ion implantation is performed to form the source region in the silicon carbide semiconductor device in accordance with the preferred embodiment;

FIG. 17 is a cross-sectional view showing an exemplary process until a gate electrode is formed in the silicon carbide semiconductor device in accordance with the preferred embodiment;

FIG. 18 is a cross-sectional view showing an exemplary process until an interlayer oxide film is formed in the silicon carbide semiconductor device in accordance with the preferred embodiment;

FIG. 19 is a cross-sectional view showing an exemplary process until a contact is formed in the silicon carbide semiconductor device in accordance with the preferred embodiment;

FIG. 20 is a cross-sectional view showing an exemplary process until a wiring is formed in the silicon carbide semiconductor device in accordance with the preferred embodiment;

FIG. 21 is a cross-sectional view showing an exemplary process until the wiring is formed in the silicon carbide semiconductor device in accordance with the preferred embodiment;

FIG. 22 is a cross-sectional view showing another exemplary structure in the case where a position of the pattern deviates from the recessed portion serving as a mark when photolithography is performed;

FIG. 23 is a cross-sectional view showing an exemplary process until the ion implantation is performed to form the source region in the silicon carbide semiconductor device in accordance with the preferred embodiment;

FIG. 24 is a cross-sectional view showing an exemplary process until the interlayer oxide film is formed in the silicon carbide semiconductor device in accordance with the preferred embodiment;

FIG. 25 is a cross-sectional view showing the exemplary process until the interlayer oxide film is formed in the silicon carbide semiconductor device in accordance with the preferred embodiment;

FIG. 26 is a cross-sectional view showing an exemplary process until the contact is formed in the silicon carbide semiconductor device in accordance with the preferred embodiment;

FIG. 27 is a cross-sectional view showing the exemplary process until the contact is formed in the silicon carbide semiconductor device in accordance with the preferred embodiment;

FIG. 28 is a cross-sectional view showing an exemplary process until the wiring is formed in the silicon carbide semiconductor device in accordance with the preferred embodiment;

FIG. 29 is a cross-sectional view showing the exemplary process until the wiring is formed in the silicon carbide semiconductor device in accordance with the preferred embodiment;

FIG. 30 is a cross-sectional view showing the exemplary process until the wiring is formed in the silicon carbide semiconductor device in accordance with the preferred embodiment; and

FIG. 31 is a cross-sectional view showing the exemplary process until the wiring is formed in the silicon carbide semiconductor device in accordance with the preferred embodiment.

### DESCRIPTION OF EMBODIMENT(S)

Hereinafter, with reference to attached figures, the preferred embodiment will be described.

Figures are schematically shown, and for convenience of illustration, omission of some constituent elements or simplification of a structure will be made as appropriate. Further, the correlation in the size and position of a structure or the like shown in different figures is not always represented accurately but may be changed as appropriate.

In the following description, identical constituent elements are represented by the same reference signs and each have the same name and function. Therefore, detailed description thereof will be omitted to avoid duplication in some cases.

Further, in the following description, even in a case of using words such as “upper”, “lower”, “left”, “right”, “side”, “bottom”, “front”, “back”, and the like, which mean specific positions and directions, these words are used for convenience to easily understand the content of the preferred embodiment, and have no relation to actual directions used when the embodiment is carried out.

Furthermore, in the following description, even in a case of using ordinal numbers such as “first”, “second”, and the like, these words are used for convenience to easily understand the content of the preferred embodiment, and the content is not limited to the order or the like which is represented by these ordinal numbers.

### The Preferred Embodiment

Hereinafter, a silicon carbide semiconductor device and a method of manufacturing a silicon carbide semiconductor device in accordance with the present preferred embodiment will be described. Further, in the following description, it is assumed that a first conductivity type is N type and a second conductivity type is P type.

<Structure of Silicon Carbide Semiconductor Device>

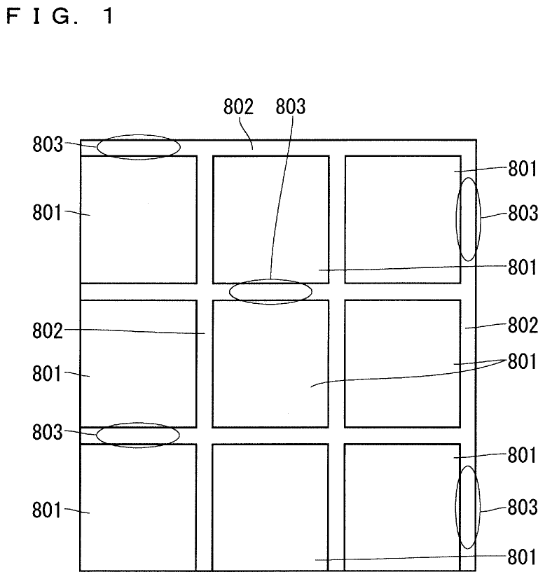

FIG. 1 is a plan view showing an exemplary arrangement form of MOSFETs and marks in accordance with the present preferred embodiment. FIG. 1 exemplarily shows a MOSFET region 801 that is a region in which a MOSFET is disposed, a scribe region 802 that is a region provided between the MOSFET regions 801, and a mark region 803 that is a region in which a mark is disposed.

As exemplarily shown in FIG. 1, a plurality of MOSFET regions 801 are arranged in a plan view. Further, the mark region 803 is partially provided in the scribe region 802.

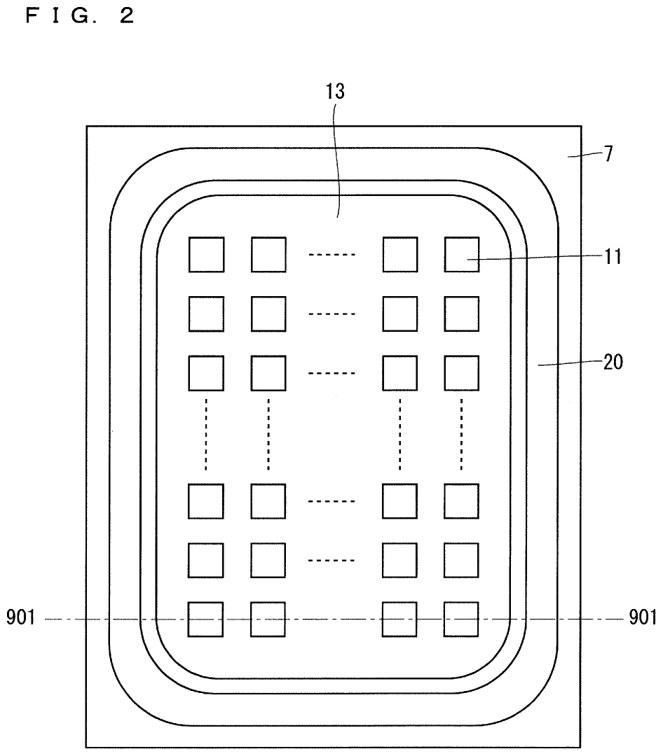

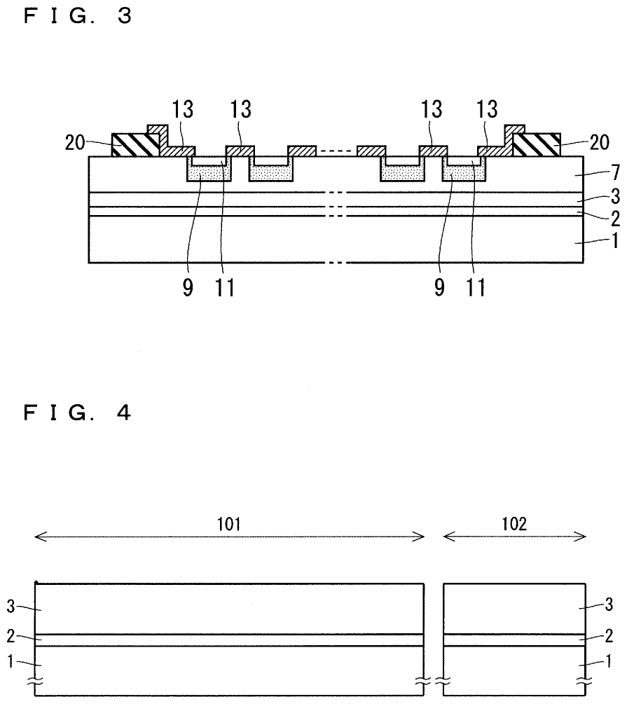

FIG. 2 is a plan view schematically showing an exemplary structure of a silicon carbide semiconductor device in accordance with the present preferred embodiment. Further, FIG. 3 is a cross-sectional view corresponding to a cross section 901 of FIG. 2.

As exemplarily shown in FIGS. 2 and 3, the silicon carbide semiconductor device includes an N-type SiC substrate 1, an N-type buffer layer 2 formed on an upper surface of the SiC substrate 1, an N-type epitaxial layer 3 formed on an upper surface of the buffer layer 2, a drain region 7 which is an N-type diffusion layer and formed in a surface layer of the epitaxial layer 3, a back gate region 9 which is a P-type diffusion layer and partially formed in a surface layer of the drain region 7, a source region 11 which is an N-type diffusion layer and partially formed in a surface layer of the back gate region 9, a gate electrode 13 which is formed on the back gate region 9 sandwiched between the source region 11 and the drain region 7, with a gate oxide film interposed therebetween, and a tetraethoxysilane (i.e., TEOS) oxide film 20 which is formed on the drain region 7. Further, in FIGS. 2 and 3, the gate electrode 13 is also formed, extending over the TEOS oxide film 20.

FIG. 4 is a cross-sectional view showing an exemplary process until an epitaxial layer is formed in the silicon carbide semiconductor device in accordance with the present preferred embodiment. In FIG. 4, exemplarily shown are a MOSFET region 101 that is a region in which the MOSFET is disposed and a mark region 102 that is a region in which the mark is disposed.

As exemplarily shown in FIG. 4, in the MOSFET region 101 and the mark region 102, the N-type buffer layer 2 is grown on the upper surface of the N-type SiC substrate 1, and further the N-type epitaxial layer 3 is grown on the upper surface of the buffer layer 2.

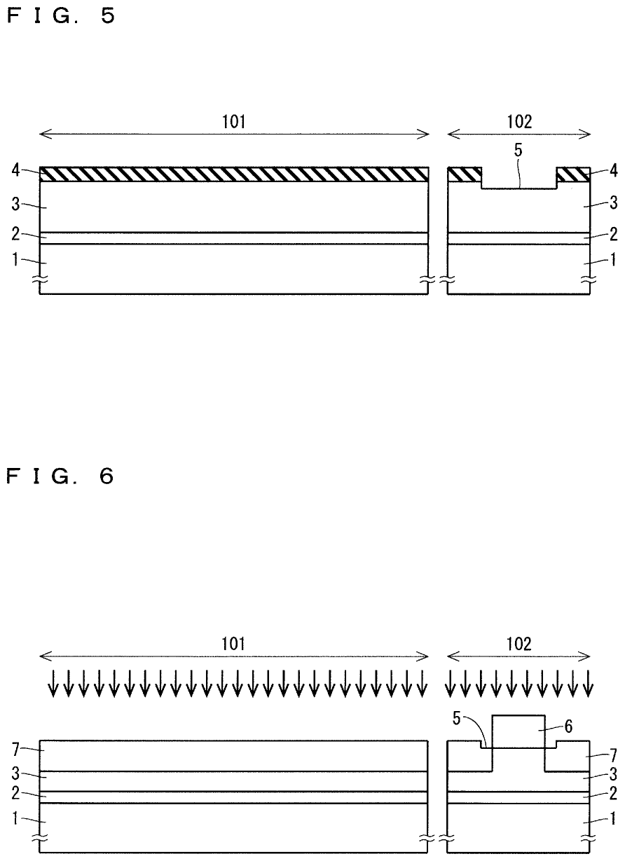

FIG. 5 is a cross-sectional view showing an exemplary process until a mark is formed in the silicon carbide semiconductor device in accordance with the present preferred embodiment. Similarly in FIG. 5, exemplarily shown are the MOSFET region 101 and the mark region 102.

As exemplarily shown in FIG. 5, a TEOS oxide film 4 is deposited on an upper surface of the epitaxial layer 3. Then, the TEOS oxide film 4 in the mark region 102 is partially removed by performing photolithography. Further, a recessed portion 5 is formed by dry etching on the upper surface of the epitaxial layer 3 which is exposed by removing the TEOS oxide film 4. The recessed portion 5 in the mark region 102, which is formed thus, serves as a mark used for the photolithography until the gate electrode 13 is formed.

FIG. 6 is a cross-sectional view showing an exemplary process until ion implantation is performed to form a drain region in the silicon carbide semiconductor device in accordance with the present preferred embodiment. Similarly in FIG. 6, exemplarily shown are the MOSFET region 101 and the mark region 102.

As exemplarily shown in FIG. 6, a resist is applied onto the upper surface of the epitaxial layer 3 from which the TEOS oxide film 4 is removed, and further photolithography is performed. At that time, when an exposure is performed while a mark of a resist mask is aligned with the recessed portion 5 in the mark region 102, a pattern 6 can be formed.

Then, after the photolithography, by implanting nitrogen or phosphorus which is an N-type ionic species from the upper surface of the epitaxial layer 3, formed is the drain region 7 for reducing resistance of the drain region.

Next, by implanting aluminum, boron, or BF₂ which is a P-type ionic species into the drain region which is several tens to several hundreds ttm away from the MOSFET region 101 (i.e., a region outside the TEOS oxide film 20 shown in FIG. 2), formed is a ring-shaped P-type diffusion layer (herein, not shown) for increasing an off-state breakdown voltage.

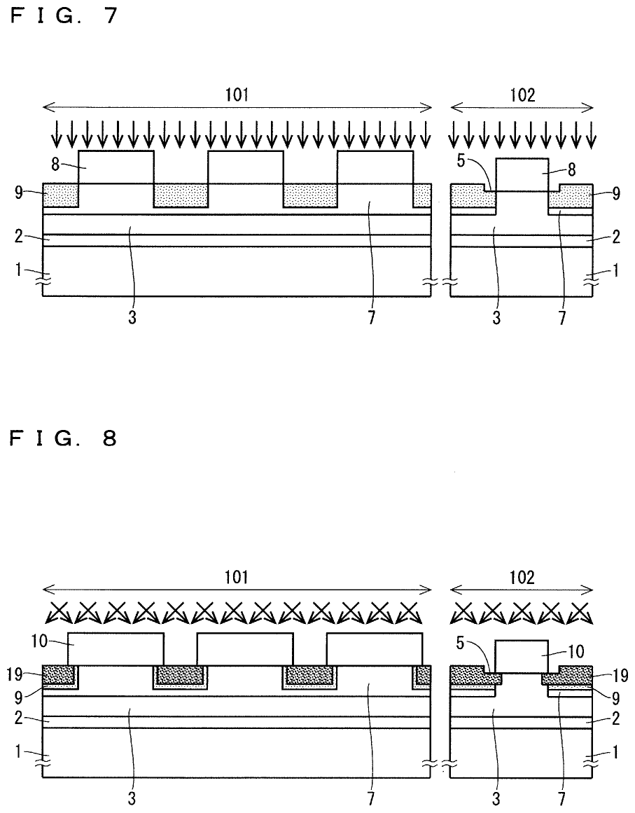

FIG. 7 is a cross-sectional view showing an exemplary process until the ion implantation is performed to form a back gate region in the silicon carbide semiconductor device in accordance with the present preferred embodiment. Similarly in FIG. 7, exemplarily shown are the MOSFET region 101 and the mark region 102.

As exemplarily shown in FIG. 7, a resist is applied onto an upper surface of the drain region 7, and further photolithography is performed by using the recessed portion 5 as a mark. Then, by forming a pattern 8 on the resist and implanting aluminum, boron, or BF₂ which is a P-type ionic species, the back gate region 9 which is a P-type diffusion layer is formed. Herein, the implantation of the P-type ionic species may be performed a plurality of times with an implantation energy changed.

FIG. 8 is a cross-sectional view showing an exemplary process until the ion implantation is performed to form a P-type diffusion layer in the silicon carbide semiconductor device in accordance with the present preferred embodiment. Similarly in FIG. 8, exemplarily shown are the MOSFET region 101 and the mark region 102.

As exemplarily shown in FIG. 8, after removing the pattern 8, a resist is applied onto an upper surface of the back gate region 9 and the upper surface of the drain region 7 and photolithography is performed by using the recessed portion 5 as a mark. Then, by forming a pattern 10 on the resist and rotationally implanting aluminum, boron, or BF₂ which is a P-type ionic species at an angle larger than 0 degrees and not larger than 45 degrees and at an energy of 80 keV or less, a P-type diffusion layer 19 is formed.

When an implantation angle is made smaller, the P-type diffusion layer 19 can be formed to be shallower. In other words, it is possible to adjust the depth of the P-type diffusion layer 19 by changing the implantation angle.

Herein, the implantation of the P-type ionic species may be performed a plurality of times with the implantation angle and the implantation energy changed. Further, also in the case where the ion implantation is performed a plurality of times, the energy is 80 keV or less. Furthermore, in forming the pattern 10 on the resist, the pattern 10 is formed also over ends of the back gate regions 9.

Herein, the rotational implantation is a method of implanting ions while rotating the ions with the normal of a target surface into which the ions are implanted, as an axis, and inclining the ions with respect to the target surface.

The P-type diffusion layer 19 is formed to be deeper than the source region 11 into which ions are continuously implanted in later processes, for example, by 0.5 μm. Then, when the P-type diffusion layer 19 is formed to have such a depth, it is not necessary to perform ion implantation at an energy of 100 keV or more. For this reason, there occurs no charging of the resist, foaming, or the like due to the ion implantation.

Further, the carrier concentration of the P-type diffusion layer 19 due to the ion implantation is almost equal to that of the back gate region 9 which is the P-type diffusion layer due to the ion implantation.

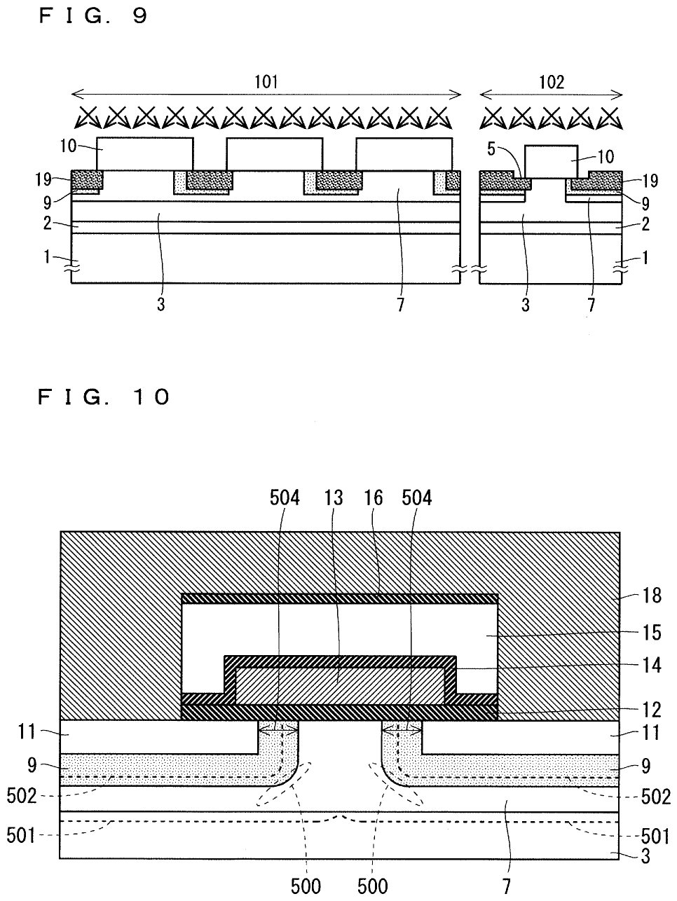

FIG. 9 is a cross-sectional view showing an exemplary structure in a case where a position of the pattern 10 deviates from the recessed portion 5 serving as a mark when photolithography is performed. Further, FIG. 10 is a cross-sectional view used for explaining the principle of off-state breakdown voltage in the silicon carbide semiconductor device in accordance with the present preferred embodiment.

In the cross-sectional view of the semiconductor device of FIG. 9, the P-type diffusion layer 19 is formed asymmetric with respect to the back gate region 9. In FIG. 9, the P-type diffusion layer 19 is formed, extending off the back gate region 9, and in other words, the P-type diffusion layer 19 is formed at a position in contact with the back gate region 9 and the drain region 7.

Further, in a case where the P-type diffusion layer 19 is formed inside the back gate region 9, the width of the back gate region 9 on the right side of the P-type diffusion layer 19 in FIG. 9 is different from that of the back gate region 9 on the left side of the P-type diffusion layer 19 in FIG. 9.

In the above-described asymmetric structure, since the mask used for forming the N-type source region 11 can be used as a mask for forming the P-type diffusion layer 19, it is not necessary to prepare another mask. Further, since the P-type diffusion layer 19 can be formed outside the N-type source region 11 so as to cover the region a predetermined distance away therefrom, it is possible to necessarily ensure a certain distance or more between the N-type source region 11 and the N-type drain region 7. Therefore, there occurs no breakdown voltage failure.

FIG. 22 is a cross-sectional view showing another exemplary structure in the case where a position of the pattern 10 deviates from the recessed portion 5 serving as a mark when photolithography is performed.

In the cross-sectional view of the semiconductor device of FIG. 22, the P-type diffusion layer 19 is formed asymmetric with respect to the back gate region 9. In FIG. 22, the distance between the P-type diffusion layer 19 and the drain region 7 on the right side of the P-type diffusion layer 19 is different from that on the left side of the P-type diffusion layer 19. Specifically, an interval 557 on the right side of the P-type diffusion layer 19 is smaller than an interval 558 on the left side of the P-type diffusion layer 19.

In FIG. 9, due to the deviation of the position of the pattern 10, the width 551 of the P-type diffusion layer 19 overlapping the gate oxide film 12 positioned on the right side thereof in a plan view becomes larger than the width 552 of the back gate region 9 overlapping the gate oxide film 12 in a plan view, as exemplarily shown in FIG. 26 described later. Further, as exemplarily shown in FIG. 26 described later, the width 553 of the P-type diffusion layer 19 overlapping the gate oxide film 12 positioned on the left side thereof in a plan view becomes not larger than the width 554 of the back gate region 9 overlapping the gate oxide film 12 in a plan view.

As exemplarily shown in FIG. 10, the distance 504 between the drain region 7 and the source region 11 in the surface layer of the back gate region 9 is, for example, not smaller than 0.4 μm and not larger than 0.6 μm. Herein, the distance 504 corresponds to an effective channel length.

On the other hand, both in the photolithography (see FIG. 7) for forming the back gate region 9 that is a region in which the pattern 8 is formed on the resist and in the photolithography for forming the source region 11 that is a region in which the pattern 10 is formed on the resist, the recessed portion 5 is used as a mark. When the position of the pattern 10 deviates from the mark and the direction of the deviation is different, the distance 504 in FIG. 10 can be, for example, 0.4 μm that is a lower limit value.

Further, depending on the shape of the pattern 8 exemplarily shown in FIG. 7 and the shape of the pattern 10 exemplarily shown in FIGS. 8 and 9, the distance 504 in FIG. 10 can be a length not larger than the lower limit value.

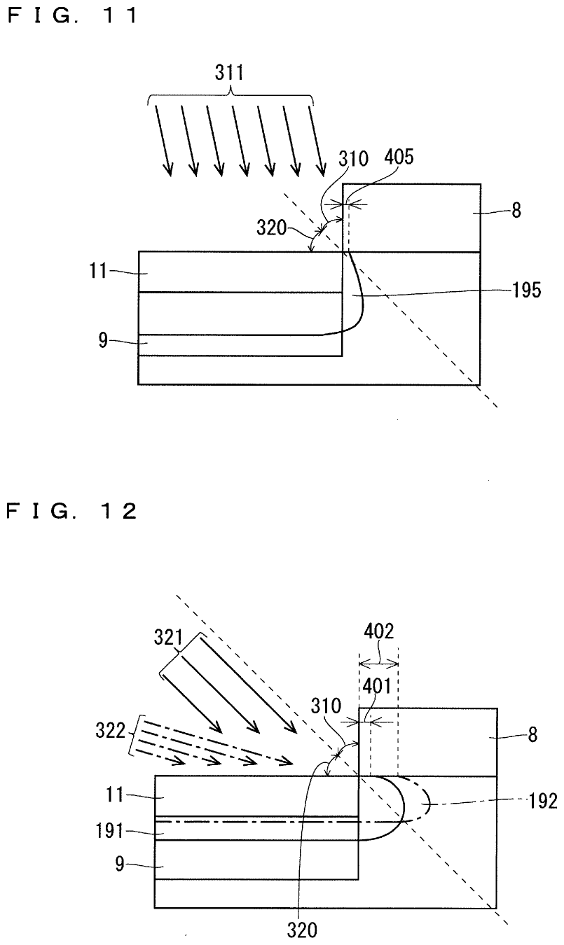

FIG. 11 is a cross-sectional view showing an exemplary structure in a case where ions are rotationally implanted at an angle of more than 45 degrees. On the other hand, FIG. 12 is a cross-sectional view showing an exemplary structure in a case where ions are rotationally implanted at an angle of not more than 45 degrees.

In FIG. 11, the angle 310 is 45 degrees, the ion implantation 311 is an ion implantation in which ions are rotationally implanted, for example, at an angle of 80 degrees larger than 45 degrees, and a P-type diffusion layer 195 is a P-type diffusion layer formed by the ion implantation 311. Further, the distance 405 is a distance between the source region 11 and the drain region 7, which is generated due to the P-type diffusion layer 195 formed by the ion implantation 311.

In FIG. 12, the angle 320 is 45 degrees, the ion implantation 321 is an ion implantation in which ions are rotationally implanted, for example, at an angle of 45 degrees, and a P-type diffusion layer 191 is a P-type diffusion layer formed by the ion implantation 321. Further, the distance 401 is a distance between the source region 11 and the drain region 7, which is generated due to the P-type diffusion layer 191 formed by the ion implantation 321.

Further, in FIG. 12, the ion implantation 322 is an ion implantation in which ions are rotationally implanted, for example, at an angle of 10 degrees not larger than 45 degrees, and a P-type diffusion layer 192 is a P-type diffusion layer formed by the ion implantation 322. Further, the distance 402 is a distance between the source region 11 and the drain region 7, which is generated due to the P-type diffusion layer 192 formed by the ion implantation 322.

As exemplarily shown in FIGS. 11 and 12, the P-type diffusion layer 195, the P-type diffusion layer 191, and the P-type diffusion layer 192 are formed in the cases where ions are rotationally implanted at an angle of more than 45 degrees, e.g., 80 degrees, where ions are rotationally implanted at an angle of not more than 45 degrees, e.g., 45 degrees, and where ions are rotationally implanted at an angle of not more than 45 degrees, e.g., 10 degrees, respectively.

When a comparison is made among the distance 405 generated due to the P-type diffusion layer 195, the distance 401 generated due to the P-type diffusion layer 191, and the distance 402 generated due to the P-type diffusion layer 192, it can be seen that as the angle of the rotationally-implanted ions with respect to the target surface increases, the distance between the source region 11 and the drain region 7 decreases.

In other words, it is possible to control the distance 504 between the source region 11 and the drain region 7 in FIG. 10 by adjusting the angle of the rotationally-implanted ions with respect to the target surface. By rotationally implanting ions at an angle in a range not smaller than 30 degrees and not larger than 45 degrees, it is possible to form the P-type diffusion layer 19 in an excellent range.

Next, with reference to FIG. 10, a mechanism of obtaining an off-state breakdown voltage of the silicon carbide semiconductor device will be described. In FIG. 10, the drain region 7 that is the N-type diffusion layer is formed on the upper surface of the N-type epitaxial layer 3 of SiC. Herein, the epitaxial layer 3 and the drain region 7 serve as drain regions.

In the surface layer of the drain region 7, the back gate region 9 that is the P-type diffusion layer is partially formed. Further, in the surface layer of the back gate region 9, the source region 11 that is the N-type diffusion layer is partially formed. Furthermore, the gate electrode 13 is formed on the back gate region 9 sandwiched between the source region 11 and the drain region 7, with the gate oxide film 12 interposed therebetween. The source region 11 extends up to the gate electrode 13 in a plan view. Further, a TEOS oxide film 14 is so formed as to cover the gate electrode 13 and a borophosphosilicate glass (BPSG) film 15 is so formed as to cover the TEOS oxide film 14. A TEOS oxide film 16 is so formed as to cover the BPSG film 15. Further, a source electrode 18 is so formed as to cover the TEOS oxide film 16 and the source region 11.

FIG. 10 shows a strong electric field portion 500, a depletion layer 501 extending toward the N-type diffusion layer, and a depletion layer 502 extending toward the P-type diffusion layer. Further, the distance 504 is a distance between the drain region 7 and the source region 11 in the surface layer of the back gate region 9.

In FIG. 10, 0 V is applied to each of the source electrode 18 and the gate electrode 13, and a voltage is applied to the epitaxial layer 3 and the drain region 7. When the voltage is applied to the epitaxial layer 3 and the drain region 7, the depletion layer 501 extends toward the N-type diffusion layer and the depletion layer 502 extends toward the P-type diffusion layer.

When the applied voltage reaches a certain voltage value, the depletion layer 501 and the depletion layer 502 each stop extending and the electric field strength increases in the strong electric field portion 500. Then, an avalanche occurs in the strong electric field portion 500. The voltage value at that time is an off-state breakdown voltage.

Therefore, when the depletion layer 502 extending toward the P-type diffusion layer reaches the source region 11 that is the N-type diffusion layer before the depletion layer 502 stops extending, a leakage current is generated between drain and source at that time, and the off-state breakdown voltage decreases. For this reason, as the distance 504 that is a distance between the drain region 7 and the source region 11 decreases, a margin of the depletion layer 502 decreases.

Immediately after the ion implantation is performed to form the source region 11, the P-type ionic species is rotationally implanted at an angle of 45 degrees or less by using the resist mask which is used for forming the source region 11, the P-type diffusion layer 19 is formed. Then, due to the P-type diffusion layer 19, the distance 504 that is a distance between the source region 11 and the drain region 7 becomes larger than the width of the depletion layer extending toward the P-type diffusion layer. For this reason, it is possible to suppress reduction in the off-state breakdown voltage.

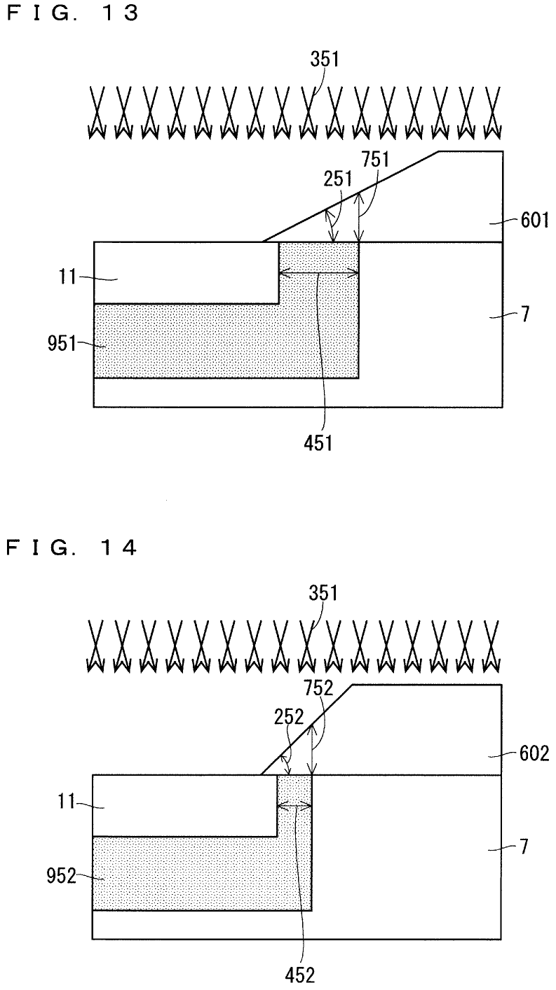

FIG. 13 is a cross-sectional view in a case where the angle at an end portion of the resist used for formation of the P-type diffusion layer and the source region is 30 degrees. Further, FIG. 14 is a cross-sectional view in a case where the angle at the end portion of the resist used for formation of the P-type diffusion layer and the source region is 45 degrees. Furthermore, FIG. 15 is a cross-sectional view in a case where the angle at the end portion of the resist used for formation of the P-type diffusion layer and the source region is 80 degrees.

As exemplarily shown in FIGS. 13, 14, and 15, in forming the P-type diffusion layer, respective shapes of the resist end portions after the photolithography are formed to be a trapezoid 601, a trapezoid 602, and a trapezoid 603, in other words, the respective resist end portions are tapered, and the P-type ionic species is rotationally implanted therein and further the N-type ionic species for forming the source region 11 is implanted therein by using the same resist. Furthermore, in FIGS. 13, 14, and 15, the rotational implantation of the P-type ionic species is represented as ion implantation 351.

As exemplarily shown in FIG. 13, in a case where the angle 251 that is a tilt angle of the resist end portion is 30 degrees, due to a P-type diffusion layer 951 formed by the rotational implantation of the P-type ionic species, a distance 451 is generated between the source region 11 and the drain region 7. Further, the P-type diffusion layer 951 is formed immediately below the resist having a thickness smaller than the thickness 751 of the resist which the P-type ionic species penetrates in the ion implantation.

Further, as exemplarily shown in FIG. 14, in a case where the angle 252 that is a tilt angle of the resist end portion is 45 degrees, due to a P-type diffusion layer 952 formed by the rotational implantation of the P-type ionic species, a distance 452 is generated between the source region 11 and the drain region 7. Further, the P-type diffusion layer 952 is formed immediately below the resist having a thickness smaller than the thickness 752 of the resist which the P-type ionic species penetrates in the ion implantation.

Further, as exemplarily shown in FIG. 15, in a case where the angle 253 that is a tilt angle of the resist end portion is 80 degrees, due to a P-type diffusion layer 953 formed by the rotational implantation of the P-type ionic species, a distance 453 is generated between the source region 11 and the drain region 7. Further, the P-type diffusion layer 953 is formed immediately below the resist having a thickness smaller than the thickness 753 of the resist which the P-type ionic species penetrates in the ion implantation.

When a comparison is made among the cases where the angle 251 of the resist end portion is 30 degrees, where the angle 252 of the resist end portion is 45 degrees, and where the angle 253 of the resist end portion is 80 degrees, it can be seen that as the angle of the resist end portion increases, the distance between the source region 11 and the drain region 7 decreases.

Therefore, unless the tilt angle of the resist end portion is formed with high accuracy, the distance between the drain region and the source region varies, and the off-state breakdown voltage of the MOSFET decreases. In other words, it is possible to adjust the distance between the drain region and the source region by controlling the tilt angle of the resist end portion. Since an exposure device for forming a resist is configured to give light perpendicularly to the resist, the shape of the resist end portion is formed to be almost perpendicular. The method in which no tilt angle is given to the resist is preferable in terms of easier formation.

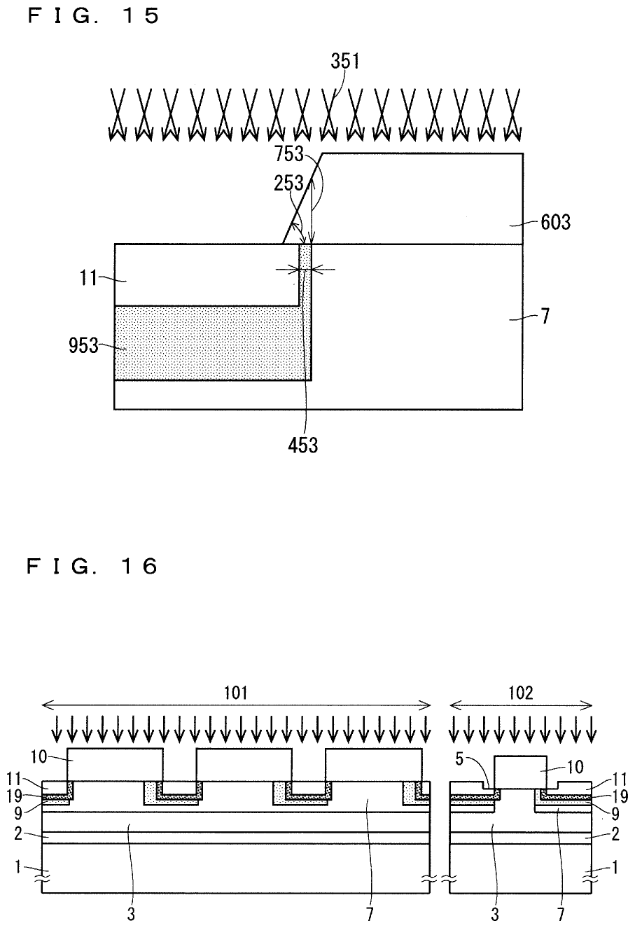

FIG. 16 is a cross-sectional view showing an exemplary process until the ion implantation is performed to form the source region in the silicon carbide semiconductor device in accordance with the present preferred embodiment. Similarly in FIG. 16, exemplarily shown are the MOSFET region 101 and the mark region 102.

By continuous implantation of nitrogen, phosphorus, or arsenic which is an N-type ionic species, using the pattern 10, into the surface layer of the P-type diffusion layer 19 formed by rotationally implanting ions at an angle of 45 degrees or less, the source region 11 is formed. In this case, the source region 11 is formed to be shallower than the P-type diffusion layer 19. Further, the ion implantation for forming the source region 11 may be performed before the formation of the P-type diffusion layer 19.

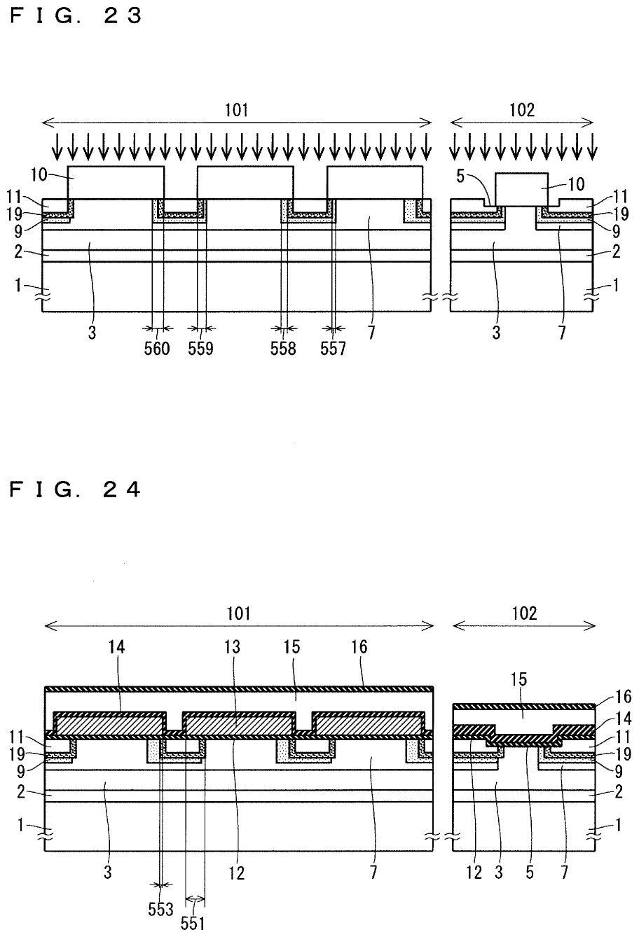

FIG. 23 is a cross-sectional view showing an exemplary process until the ion implantation is performed to form the source region in the silicon carbide semiconductor device in accordance with the present preferred embodiment.

The structure shown in FIG. 23 is formed by using the same resist as that used for forming the P-type diffusion layer 19 of FIG. 22 which is asymmetrically formed. For this reason, the distance between the N-type source region 11 and the N-type drain region 7 on the right side of the N-type source region 11 is different from that on the left side of the N-type source region 11. Specifically, an interval 559 on the right side of the N-type source region 11 is smaller than an interval 560 on the left side of the N-type source region 11.

Since the interval 559 becomes smaller, the depletion layer extends from the drain region 7 against the impurity concentration of only the back gate region 9 that is the P-type diffusion layer, as described with reference to FIG. 10. Then, the depletion layer reaches the N-type source region 11 with a low voltage. As a result, a breakdown voltage failure occurs.

By adding the P-type diffusion layer 19, however, the total concentration of the P-type diffusion layers existing between the N-type source region 11 and the N-type drain region 7 increases, and it is thereby possible to suppress the extension of the depletion layer. Therefore, there occurs no reduction in the breakdown voltage.

Next, in order to activate the drain region 7, the back gate region 9, the P-type diffusion layer 19, and the source region 11, an annealing process is performed at 1700° C. or more. In performing the annealing process at 1700° C. or more, in order to avoid digestion of Si, a carbon-based film such as a graphite film or the like is formed before performing the annealing process. Then, after the annealing process, the carbon-based film is removed (herein, not shown).

Next, the TEOS oxide film is deposited to have a thickness not smaller than 800 nm and not larger than 1500 nm on the upper surface of the drain region 7 and photolithography is performed. Then, the TEOS oxide film is etched and a field oxide film is thereby formed (herein, not shown).

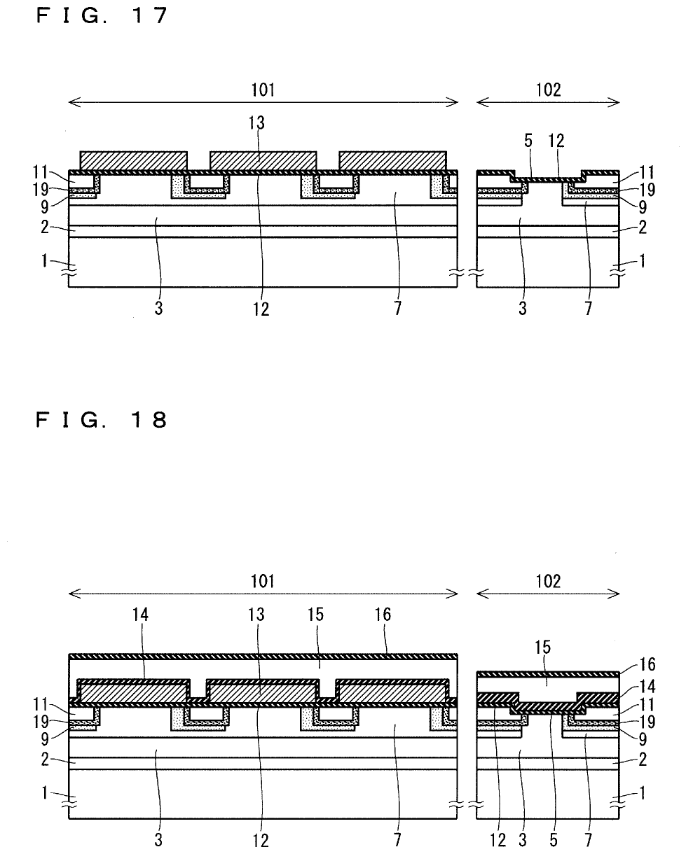

FIG. 17 is a cross-sectional view showing an exemplary process until the gate electrode is formed in the silicon carbide semiconductor device in accordance with the present preferred embodiment. Similarly in FIG. 17, exemplarily shown are the MOSFET region 101 and the mark region 102.

As exemplarily shown in FIG. 17, the upper surfaces of the drain region 7, the back gate region 9, and the P-type diffusion layer 19, and the source region 11 which are activated by the annealing process are oxidized and the gate oxide film 12 having a thickness not smaller than 30 nm and not larger than 70 nm, for example, is thereby formed.

Next, N-type polysilicon is deposited on an upper surface of the gate oxide film 12 and further photolithography is performed. Then, the polysilicon is dry-etched, to thereby form the gate electrode 13.

Herein, the gate oxide film 12 is formed to be in contact with the surface of the back gate region 9 sandwiched between the drain region 7 and the source region 11 and the surface of the P-type diffusion layer 19 sandwiched between the drain region 7 and the source region 11.

FIG. 18 is a cross-sectional view showing an exemplary process until an interlayer oxide film is formed in the silicon carbide semiconductor device in accordance with the present preferred embodiment. Similarly in FIG. 18, exemplarily shown are the MOSFET region 101 and the mark region 102.

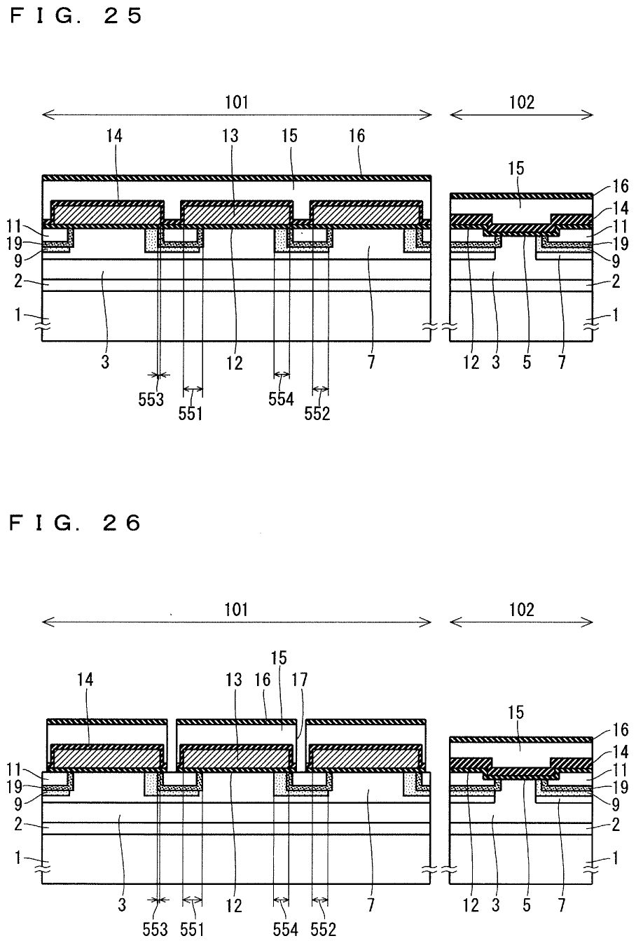

FIG. 24 is a cross-sectional view showing an exemplary process until the interlayer oxide film is formed in the silicon carbide semiconductor device in accordance with the present preferred embodiment. Similarly in FIG. 24, exemplarily shown are the MOSFET region 101 and the mark region 102.

FIG. 25 is a cross-sectional view showing the exemplary process until the interlayer oxide film is formed in the silicon carbide semiconductor device in accordance with the present preferred embodiment. Similarly in FIG. 25, exemplarily shown are the MOSFET region 101 and the mark region 102.

Due to the deviation of the position of the pattern 10, as exemplarily shown in FIGS. 24 and 25, the width 551 of the P-type diffusion layer 19 overlapping the gate oxide film 12 positioned on the right side thereof in a plan view becomes larger than the width 552 of the back gate region 9 overlapping the gate oxide film 12 in a plan view.

Further, as exemplarily shown in FIGS. 24 and 25, the width 553 of the P-type diffusion layer 19 overlapping the gate oxide film 12 positioned on the left side thereof in a plan view becomes not larger than the width 554 of the back gate region 9 overlapping the gate oxide film 12 in a plan view.

As exemplarily shown in FIG. 18, the TEOS oxide film 14 is so deposited as to cover the gate oxide film 12 and the gate electrode 13, and further the BPSG film 15 is so deposited on an upper surface of the TEOS oxide film 14 as to have a thickness not smaller than 300 nm and not larger than 1000 nm. Then, the TEOS oxide film 16 is deposited again on an upper surface of the BPSG film 15, to thereby form an interlayer oxide film.

FIG. 19 is a cross-sectional view showing an exemplary process until a contact is formed in the silicon carbide semiconductor device in accordance with the present preferred embodiment. Similarly in FIG. 19, exemplarily shown are the MOSFET region 101 and the mark region 102.

FIG. 26 is a cross-sectional view showing an exemplary process until the contact is formed in the silicon carbide semiconductor device in accordance with the present preferred embodiment. Similarly in FIG. 26, exemplarily shown are the MOSFET region 101 and the mark region 102.

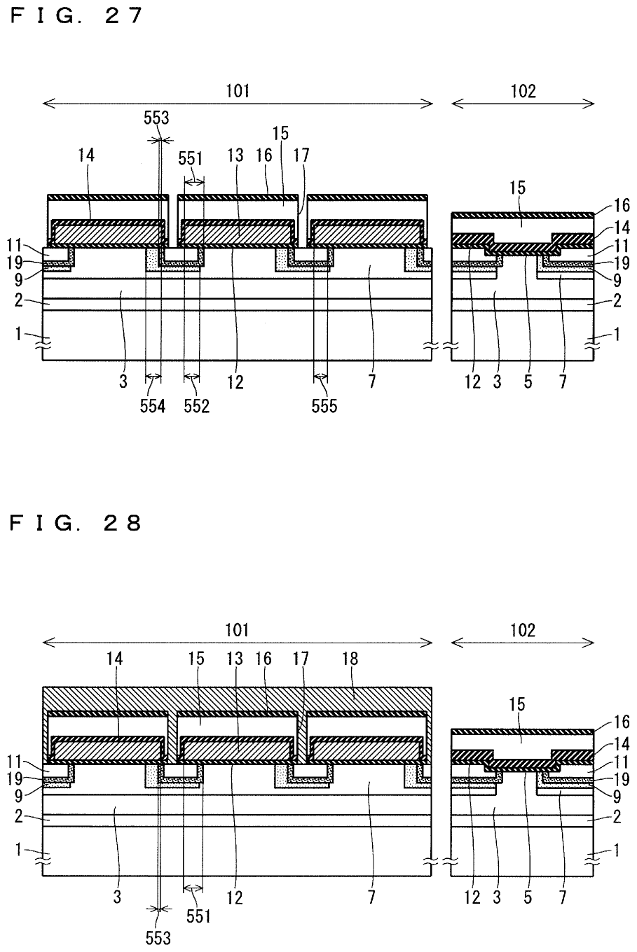

FIG. 27 is a cross-sectional view showing the exemplary process until the contact is formed in the silicon carbide semiconductor device in accordance with the present preferred embodiment. Similarly in FIG. 27, exemplarily shown are the MOSFET region 101 and the mark region 102.

A resist is applied onto an upper surface of the TEOS oxide film 16, and further photolithography is performed. Then, wet etching is performed and after that, dry etching is performed, to thereby form the contact 17 as exemplarily shown in FIG. 19.

The etching of the TEOS oxide film 16, the BPSG film 15, and the TEOS oxide film 14 in forming the contact may be only dry etching, or may be wet etching after dry etching.

Herein, a pair of gate oxide films 12 sandwiching the contact 17 are each in contact with part of the surface of the source region 11. Then, the width 555 of the source region 11 overlapping the gate oxide film 12 positioned on the right side of the contact 17 in a plan view is larger than the width of the source region 11 overlapping the gate oxide film 12 positioned on the left side of the contact 17 in a plan view (see FIG. 27).

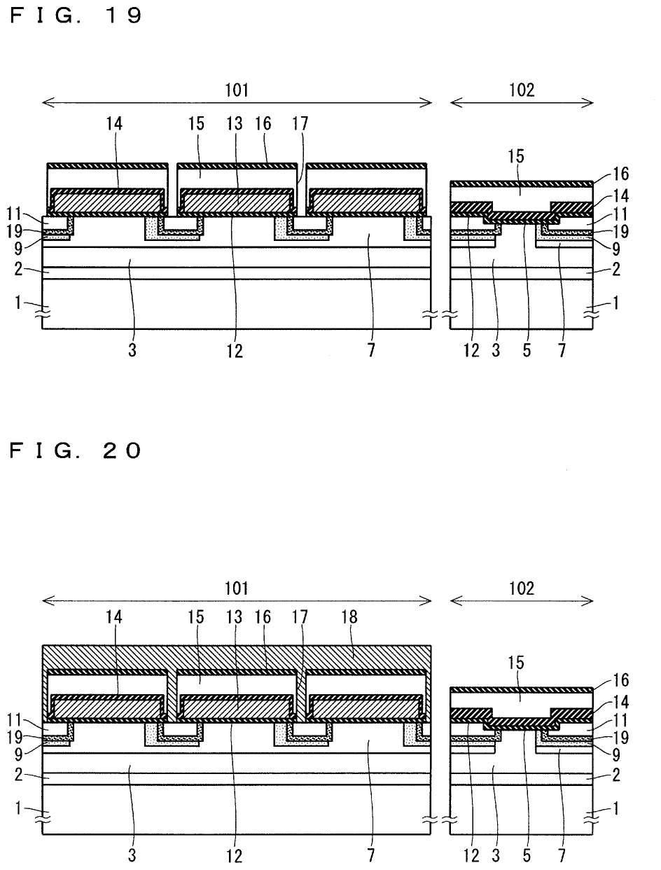

FIG. 20 is a cross-sectional view showing an exemplary process until a wiring is formed in the silicon carbide semiconductor device in accordance with the present preferred embodiment. Similarly in FIG. 20, exemplarily shown are the MOSFET region 101 and the mark region 102.

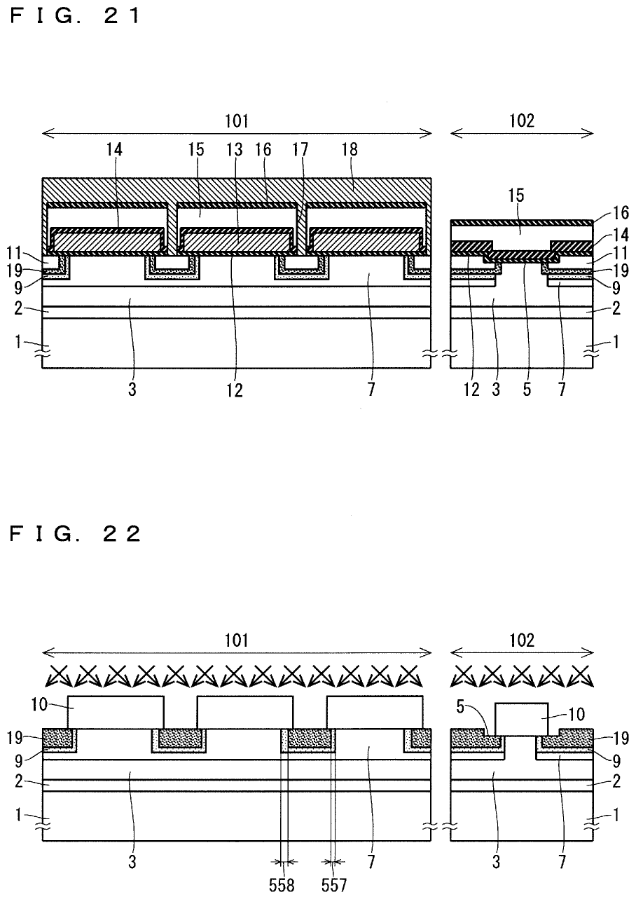

Further, FIG. 21 is a cross-sectional view showing an exemplary process until the wiring is formed in the silicon carbide semiconductor device in accordance with the present preferred embodiment. Similarly in FIG. 21, exemplarily shown are the MOSFET region 101 and the mark region 102.

First, in order to reduce the contact resistance on an outermost surface, Ni is sputtered, and further photolithography is performed. Then, Ni formed on the surface except that of the source region 11 exposed after formation of the contact is removed, and further heat treatment is performed, to thereby form NiSi (herein, not shown).

Next, aluminum or AlSi for wiring is sputtered, and further photolithography is performed. Then, this aluminum or AlSi is removed, and a wiring (i.e., source electrode 18) as exemplarily shown in FIG. 20 is thereby formed.

Next, a SiN film or a conductive nitride film is deposited on an outermost surface. Finally, polyimide is deposited (herein, not shown).

FIG. 20 is a cross-sectional view showing an exemplary structure in a case where a mask misalignment occurs when the P-type diffusion layer 19 is formed by rotationally implanting ions at an angle of 45 degrees.

As exemplarily shown in FIG. 20, the P-type diffusion layer 19 is formed, extending over the surface layer of the drain region 7 and the surface layer of the back gate region 9. Further, the P-type diffusion layer 19 is formed to be shallower than the back gate region 9.

Furthermore, the width of the P-type diffusion layer 19 overlapping the gate oxide film 12 positioned on the right side of the contact 17 in a plan view is larger than the width of the P-type diffusion layer 19 overlapping the gate oxide film 12 positioned on the left side of the contact 17 in a plan view.

As exemplarily shown in FIG. 20, the back gate region 9 and the P-type diffusion layer 19 which are P-type diffusion layers in the vicinity of an edge of the gate electrode 13 have a left-right asymmetric shape. In other words, the widths (i.e., the width 551 and the width 553) of the P-type diffusion layer 19 overlapping the gate oxide film 12 on the right side and the left side of the contact 17, respectively, in a plan view are different from each other.

Further, the widths of the back gate region 9 which is the P-type diffusion layer overlapping the gate oxide film 12 on the right side and the left side of the contact 17, respectively, in a plan view are equal to each other.

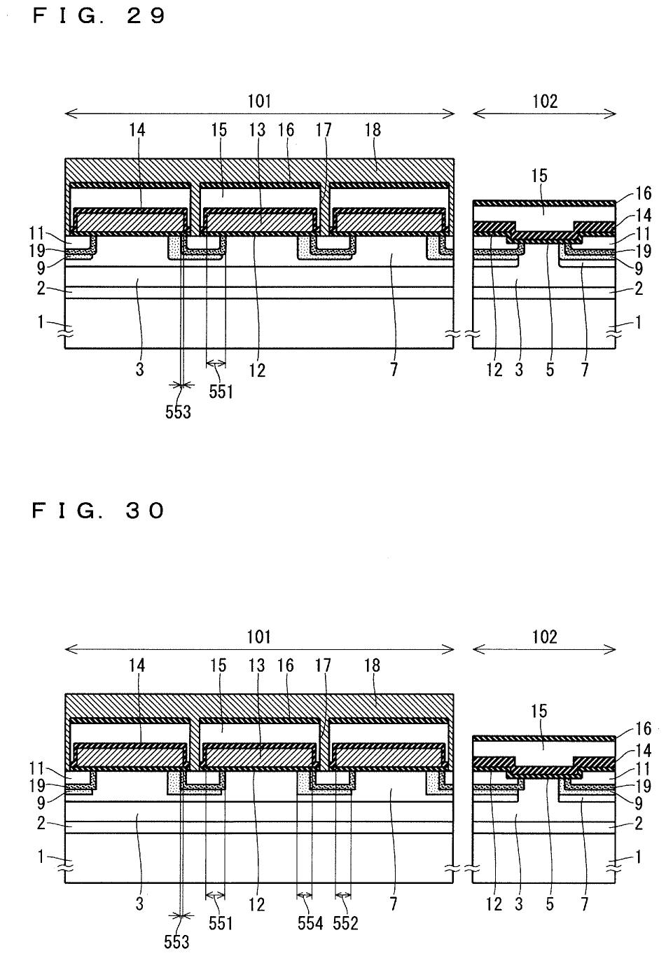

FIGS. 28, 29, 30, and 31 are cross-sectional views each showing an exemplary process until the wiring is formed in the silicon carbide semiconductor device in accordance with the present preferred embodiment.

In FIGS. 28, 29, 30, and 31, the widths of the back gate region 9 which is the P-type diffusion layer overlapping the gate oxide film 12 on the right side and the left side of the contact 17, respectively, in a plan view are different from each other. Specifically, the width 552 on the right side of the contact 17 is smaller than the width 554 on the left side of the contact 17.

In FIGS. 28, 29, 30, and 31, the P-type diffusion layer 19 inside which the source region 11 is formed and the back gate region 9 are formed asymmetrically. In other words, the center in a left and right direction of the P-type diffusion layer 19 inside which the source region 11 is formed deviates from the center of the back gate region 9 in the left and right direction. Then, the width of the back gate region 9 on the left side of the P-type diffusion layer 19 inside which the source region 11 is formed is different from that of the back gate region 9 on the right side of the P-type diffusion layer 19 inside which the source region 11 is formed.

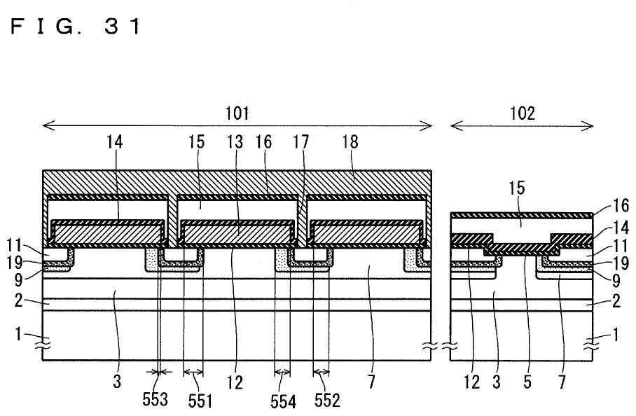

In FIGS. 29 and 31, when ion implantation is performed on the P-type back gate region 9 and annealing is performed thereon for activation thereof after that, since the diffusion coefficient of the P-type back gate region 9 is lower than that of Si, there occurs almost no diffusion but a corner of a junction bottom thereof is rounded. Similarly in the case where the P-type back gate region 9 is formed by ion implantation, a corner of a junction bottom of the P-type diffusion layer 19 is also rounded.

When the corners of the junction bottoms of the P-type back gate region 9 and the P-type diffusion layer 19 are rounded, since the depletion layer in the P-type diffusion region extends more smoothly, it is possible to suppress variation in the breakdown voltage.

On the other hand, FIG. 21 is a cross-sectional view showing an exemplary structure in a case where no mask misalignment occurs when the P-type diffusion layer 19 is formed by rotationally implanting ions at an angle of 45 degrees.

As exemplarily shown in FIG. 21, in the case where no mask misalignment occurs, the back gate region 9 and the P-type diffusion layer 19 have a left-right symmetric shape. In other words, the widths of the P-type diffusion layer 19 overlapping the gate oxide film 12 on the right side and the left side of the contact 17, respectively, in a plan view are equal to each other.

Further, whether the shape of the structure is symmetric or asymmetric can be determined from a dC/dV image of the cross section by the scanning capacitance microscopy. Further, by the scanning capacitance microscopy, a profile close to the concentration distribution can be obtained from the carrier concentration distribution of the cross section.

In the conventional structure, since the P-type diffusion layer 19 is not provided, when a mask used for forming the source region 11 becomes misaligned with a mask used for forming the back gate region 9, there is a possibility that the source region 11 may extend off the back gate region 9, or a distance from the source region 11 to the back gate region 9 may become shorter.

When the P-type diffusion layer 19 is formed by rotational implantation using the mask used for forming the source region 11, however, the source region 11 can be formed inside the P-type diffusion layer 19. For this reason, even when the source region 11 extends off the back gate region 9, it is possible to maintain the electrical property of the semiconductor device and sufficiently ensure the distance from the source region 11 to the back gate region 9.

In the present preferred embodiment, even in the case where a mask misalignment occurs in the photolithography, when the P-type diffusion layer 19 is formed by rotationally implanting ions at an angle of 45 degrees, even if the source region 11 is asymmetric with respect to the gate electrode, it is possible to ensure the distance between the source region 11 and the drain region 7.

For this reason, it is possible to suppress reduction in the off-state breakdown voltage of the silicon carbide semiconductor device. This is because the off-state breakdown voltage of the silicon carbide semiconductor device depends on the depletion layer extending in the P-type diffusion layer and the depletion layer extending in the N-type diffusion layer and according to the silicon carbide semiconductor device of the present preferred embodiment, the depletion layer extending in the P-type diffusion layer does not reach the N-type diffusion layer in the source region before an avalanche occurs in the strong electric field portion 500.

Further, in a symmetric structure in which the back gate region and the source region are formed by using a trapezoidal resist, it is difficult to make the effective channel length shorter than 1.0 μm. In the present preferred embodiment, since the effective channel length shorter than 1.0 μm can be formed on the right side of the contact 17 in FIG. 20 when part of the back gate region is formed to have an asymmetric structure by rotational implantation using the same mask, the property of the silicon carbide semiconductor device can be improved.

### Effects of the Above-Described Preferred Embodiment

Next, the effects produced by the above-described preferred embodiment will be described. In the following description, though the effects based on the specific structure exemplarily shown in the above-described preferred embodiment will be described, the structures may be replaced by any other specific structure exemplarily shown in the present specification within the scope where the same effects can be produced.

In the above-described preferred embodiment, the silicon carbide semiconductor device includes a silicon carbide semiconductor layer of a first conductivity type, a second diffusion layer of a second conductivity type, a third diffusion layer of the second conductivity type, a first gate insulating film, a second gate insulating film, a first gate electrode, and a second gate electrode. Herein, the silicon carbide semiconductor layer corresponds to, for example, a buffer layer 2, an epitaxial layer 3, and a drain region 7. Further, the second diffusion layer corresponds to, for example, a back gate region 9. The third diffusion layer corresponds to, for example, a P-type diffusion layer 19. The first gate insulating film and the second gate insulating film correspond to, for example, a pair of gate oxide films 12 sandwiching one contact 17. The first gate electrode and the second gate electrode correspond to, for example, a pair of gate electrodes 13 sandwiching one contact 17. The drain region 7 is formed in a surface layer of the epitaxial layer 3. The back gate region 9 is partially formed in a surface layer of the drain region 7. The P-type diffusion layer 19 is formed, extending over the surface layer of the drain region 7 and a surface layer of the back gate region 9. In FIG. 20, the gate oxide film 12 positioned on the right side of one contact 17 is so formed as to be in contact with part of a surface of the back gate region 9 and part of a surface of the P-type diffusion layer 19. In FIG. 20, the gate oxide film 12 positioned on the left side of the contact 17 is so formed as to be in contact with another part of the surface of the back gate region 9 and another part of the surface of the P-type diffusion layer 19. In FIG. 20, the gate electrode 13 positioned on the right side of one contact 17 is so formed as to be in contact with the gate oxide film 12 which is also positioned on the right side of the contact 17. In FIG. 20, the gate electrode 13 positioned on the left side of one contact 17 is so formed as to be in contact with the gate oxide film 12 which is also positioned on the left side of the contact 17. The P-type diffusion layer 19 is formed to be shallower than the back gate region 9. Further, the width of the P-type diffusion layer 19 overlapping the gate oxide film 12 positioned on the right side of one contact 17 in a plan view is larger than the width of the P-type diffusion layer 19 overlapping the gate oxide film 12 positioned on the left side of the contact 17 in a plan view.

In such a configuration, even in a case where a formation position of the source region 11 deviates from that of the back gate region 9 and the distance between the source region 11 and the drain region 7 becomes small, since the distance between the source region 11 and the drain region 7 is ensured by the P-type diffusion layer 19, it is possible to suppress reduction in the off-state breakdown voltage of the silicon carbide semiconductor device. Therefore, the yield is improved.

Further, even in a case where at least one of the other constituent elements exemplarily shown in the present specification is added to the above-described constituent elements as appropriate, i.e., a case where the other constituent elements exemplarily shown in the present specification, which are not described as the above-described constituent elements, are added to the above-described constituent elements as appropriate, the same effects can be produced.

Further, in the above-described preferred embodiment, the silicon carbide semiconductor device includes a silicon carbide semiconductor layer of a first conductivity type, a second diffusion layer of a second conductivity type, a third diffusion layer of the second conductivity type, a first gate insulating film, and a first gate electrode. Herein, the silicon carbide semiconductor layer corresponds to, for example, a buffer layer 2, an epitaxial layer 3, and a drain region 7. Further, the second diffusion layer corresponds to, for example, a back gate region 9. The third diffusion layer corresponds to, for example, a P-type diffusion layer 19. The first gate insulating film corresponds to, for example, one of gate oxide films 12 sandwiching one contact 17. The first gate electrode corresponds to, for example, one of gate electrodes 13 sandwiching one contact 17. The drain region 7 is formed in a surface layer of the epitaxial layer 3. The back gate region 9 is partially formed in a surface layer of the drain region 7. The P-type diffusion layer 19 is formed at a position in contact with the drain region 7 and the back gate region 9. In FIG. 20, the gate oxide film 12 positioned on the right side of one contact 17 is so formed as to be in contact with part of a surface of a back gate region 9 and part of a surface of the P-type diffusion layer 19. In FIG. 20, the gate oxide film 12 positioned on the left side of the contact 17 is so formed as to be in contact with another part of the surface of the back gate region 9 and another part of the surface of the P-type diffusion layer 19. In FIG. 20, the gate electrode 13 positioned on the right side of one contact 17 is so formed as to be in contact with the gate oxide film 12 which is also positioned on the right side of the contact 17. In FIG. 20, the gate electrode 13 positioned on the left side of one contact 17 is so formed as to be in contact with the gate oxide film 12 which is also positioned on the left side of the contact 17.

In such a configuration, even in a case where the formation position of the source region 11 deviates from that of the back gate region 9 and the distance between the source region 11 and the drain region 7 becomes small, since the distance between the source region 11 and the drain region 7 is ensured by the P-type diffusion layer 19, it is possible to suppress reduction in the off-state breakdown voltage of the silicon carbide semiconductor device. Therefore, the yield is improved.

Further, even in a case where at least one of the other constituent elements exemplarily shown in the present specification is added to the above-described constituent elements as appropriate, i.e., a case where the other constituent elements exemplarily shown in the present specification, which are not described as the above-described constituent elements, are added to the above-described constituent elements as appropriate, the same effects can be produced.

Furthermore, in the above-described preferred embodiment, the width of the P-type diffusion layer 19 overlapping the gate oxide film 12 positioned on the right side of one contact 17 in a plan view is larger than the width of the back gate region 9 overlapping the gate oxide film 12 in a plan view. Further, the width of the P-type diffusion layer 19 overlapping the gate oxide film 12 positioned on the left side of the contact 17 in a plan view is not larger than the width of the back gate region 9 overlapping the gate oxide film 12 in a plan view. In such a configuration, since the distance between the source region 11 and the drain region 7 is ensured by the P-type diffusion layer 19 formed extending off the back gate region 9, it is possible to suppress reduction in the off-state breakdown voltage of the silicon carbide semiconductor device.

Furthermore, in the above-described preferred embodiment, the silicon carbide semiconductor device includes a fourth diffusion layer of the first conductivity type which is partially formed in a surface layer of the P-type diffusion layer 19. Herein, the fourth diffusion layer corresponds to, for example, the source region 11. The gate oxide film 12 is so formed as to be in contact with at least the surface of the back gate region 9 sandwiched between the drain region 7 and the source region 11 and the surface of the P-type diffusion layer 19 sandwiched between the drain region 7 and the source region 11. In such a configuration, since the distance between the source region 11 and the drain region 7 is ensured by the P-type diffusion layer 19, it is possible to suppress reduction in the off-state breakdown voltage of the silicon carbide semiconductor device.

Further, in the above-described preferred embodiment, the gate oxide film 12 positioned on the right side of one contact 17 is so formed as to be in contact with part of a surface of the source region 11. Furthermore, the gate oxide film 12 positioned on the left side of the contact 17 is so foil led as to be in contact with another part of the surface of the source region 11. Further, the width of the source region 11 overlapping the gate oxide film 12 positioned on the right side of one contact 17 in a plan view is larger than the width of the source region 11 overlapping the gate oxide film 12 positioned on the left side of the contact 17 in a plan view. In such a configuration, since the distance between the source region 11 and the drain region 7 is ensured by the P-type diffusion layer 19, it is possible to suppress reduction in the off-state breakdown voltage of the silicon carbide semiconductor device.

Furthermore, in the above-described preferred embodiment, the width of the P-type diffusion layer 19 sandwiched between the drain region 7 and the source region 11, overlapping the gate oxide film 12 positioned on the right side of one contact 17 in a plan view, is smaller than 1.0 μm. In such a configuration, since the silicon carbide semiconductor device having an effective channel length shorter than 1.0 μm can be manufactured, the property of the silicon carbide semiconductor device can be improved.

In the above-described preferred embodiment, in the method of manufacturing the silicon carbide semiconductor device, a drain region 7 of a first conductivity type is formed in a surface layer of an epitaxial layer 3 of the first conductivity type by ion implantation. Then, a back gate region 9 of a second conductivity type is partially formed in a surface layer of the drain region 7 by ion implantation. Then, a resist pattern is formed on a surface of the back gate region 9. Herein, the resist pattern corresponds to, for example, a pattern 10. Then, a P-type diffusion layer 19 of the second conductivity type is formed, extending over the surface layer of the drain region 7, which is exposed from the pattern 10, and a surface layer of the back gate region 9, by ion rotational implantation at an angle of 45 degrees or less. Further, a source region 11 of the first conductivity type is partially formed in at least the surface layer of the back gate region 9, which is exposed from the pattern 10, by ion implantation. Then, a first gate insulating film and a second gate insulating film are formed on at least the surface of the back gate region 9 sandwiched between the drain region 7 and the source region 11 and a surface of the P-type diffusion layer 19 sandwiched between the drain region 7 and the source region 11. Herein, the first gate insulating film and the second gate insulating film each correspond to, for example, a gate oxide film 12. Then, a gate electrode 13 is formed on a surface of the gate oxide film 12. Herein, the P-type diffusion layer 19 is formed to be shallower than the back gate region 9. Further, the source region 11 is partially formed in a surface layer of the P-type diffusion layer 19. Furthermore, the width of the P-type diffusion layer 19 overlapping the gate oxide film 12 positioned on the right side of one contact 17 in a plan view is larger than the width of the P-type diffusion layer 19 overlapping the gate oxide film 12 positioned on the left side of the contact 17 in a plan view.

In such a configuration, even in a case where the formation position of the source region 11 deviates from that of the back gate region 9 and the distance between the source region 11 and the drain region 7 becomes small, since the distance between the source region 11 and the drain region 7 is ensured by the P-type diffusion layer 19 formed by the rotational implantation using the same resist pattern as that used for forming the source region 11. For this reason, it is possible to suppress reduction in the off-state breakdown voltage of the silicon carbide semiconductor device. Therefore, the yield is improved.

Further, even in a case where at least one of the other constituent elements exemplarily shown in the present specification is added to the above-described constituent elements as appropriate, i.e., a case where the other constituent elements exemplarily shown in the present specification, which are not described as the above-described constituent elements, are added to the above-described constituent elements as appropriate, the same effects can be produced.

Furthermore, unless there is no particular limitation, the order of performing respective processes may be changed.

Further, in the above-described preferred embodiment, the P-type diffusion layer 19 is formed by ion rotational implantation at an angle not smaller than 30 degrees and not larger than 45 degrees. In such a configuration, the distance between the source region 11 and the drain region 7 is sufficiently ensured by the P-type diffusion layer 19 formed by the ion rotational implantation at the angle in this range. For this reason, it is possible to suppress reduction in the off-state breakdown voltage of the silicon carbide semiconductor device.

Furthermore, in the above-described preferred embodiment, an end portion of the pattern 10 has a tapered shape. In such a configuration, since it is possible to control a formation range of the P-type diffusion layer 19 by the tapered shape, the distance between the source region 11 and the drain region 7 is sufficiently ensured.

### Variations of the Above-Described Preferred Embodiment

Though the above-described preferred embodiment describes, the material quality, material, dimension, shape, relative arrangement relation, implementation condition, or the like of each constituent element in some cases, these are exemplary in all aspects, and the present invention is not limited to those described in the present specification.

Therefore, an indefinite number of modifications and variations and equivalents not exemplarily shown are assumed within the scope of the technique disclosed in the present specification. Examples of these modifications and variations include, for example, cases where at least one constituent element is deformed, where at least one constituent element is added, and/or where at least one constituent element is omitted.

When the above-described preferred embodiment describes that “one” constituent element is included, “one or more” constituent elements may be included, as long as no contradiction arises.

Further, each constituent element in the above-described preferred embodiment is a conceptual unit, and the scope of the technique disclosed in the present specification includes cases where one constituent element is constituted of a plurality of structures, where one constituent element corresponds to part of a structure, and where a plurality of constituent elements are included in one structure.

Furthermore, each constituent element in the above-described preferred embodiment includes a structure having any other structure or shape, as long as the same function can be performed.

The description in the present specification can be referred to for all purposes as to the present technique, and is not recognized as the prior art.

When a material name or the like is described, not being particularly specified, in the above-described preferred embodiment, the material includes the same containing any other additive, such as an alloy or the like, as long as no contradiction arises.

Though the semiconductor substrate is an N-type one in the above-described preferred embodiment, the semiconductor substrate may be a P-type one. In other words, though the MOSFET has been described as an example of the silicon carbide semiconductor device in the above-described preferred embodiment, a case where the exemplary silicon carbide semiconductor device is an insulated gate bipolar transistor (IGBT) can be assumed.

In the case where the exemplary silicon carbide semiconductor device is an IGBT, the source electrode corresponds to an emitter electrode and a drain electrode corresponds to a collector electrode. Further, in the case where the exemplary silicon carbide semiconductor device is an IGBT, though a layer of the conductivity type opposite to that of the drift layer is positioned on the lower surface of the drift layer, the layer positioned on the lower surface of the drift layer may be a layer which is newly formed on the lower surface of the drift layer or a semiconductor substrate on which the drift layer is to be formed, like in the case described in the above preferred embodiment.

### EXPLANATION OF REFERENCE SIGNS

1 SiC substrate, 2 buffer layer, 3 epitaxial layer, 4, 14, 16, 20 TEOS oxide film, 5 recessed portion, 6, 8, 10 pattern, 7 drain region, 9 back gate region, 11 source region, 12 gate oxide film, 13 gate electrode, 15 BPSG film, 17 contact, 18 source electrode, 19, 191, 192, 195, 951, 952, 953 diffusion layer, 101, 801 MOSFET region, 102, 803 mark region, 251, 252, 253, 310, 320 angle, 311, 321, 322, 351 ion implantation, 401, 402, 405, 451, 452, 453, 504 distance, 500 strong electric field portion, 501, 502 depletion layer, 551, 552, 553, 554, 555 width, 557, 558, 559, 560, interval, 601, 602, 603 trapezoid, 751, 752, 753 thickness, 802 scribe region, 901 cross section

1. A silicon carbide semiconductor device, comprising:
a silicon carbide semiconductor layer of a first conductivity type;
a second diffusion layer of a second conductivity type which is partially formed in a surface layer of the silicon carbide semiconductor layer;
a third diffusion layer of the second conductivity type which is formed in at least part of a surface layer of the second diffusion layer; and
a fourth diffusion layer of the first conductivity type which is partially formed in a surface layer of the third diffusion layer,
wherein the third diffusion layer is formed to be shallower than the second diffusion layer,
the fourth diffusion layer is formed inside the third diffusion layer in a cross-sectional view, and
the third diffusion layer is formed at a position asymmetric with respect to the second diffusion layer in a cross-sectional view.

2. The silicon carbide semiconductor device according to claim 1, wherein
the third diffusion layer is formed at a position in contact with the silicon carbide semiconductor layer and the second diffusion layer.

3. The silicon carbide semiconductor device according to claim 1, further comprising:
a first gate insulating film formed to be in contact with part of a surface of the second diffusion layer and part of a surface of the third diffusion layer;
a second gate insulating film formed to be in contact with another part of the surface of the second diffusion layer and another part of the surface of the third diffusion layer;
a first gate electrode formed to be in contact with the first gate insulating film; and
a second gate electrode formed to be in contact with the second gate insulating film.

4. The silicon carbide semiconductor device according to claim 3, wherein
the width of the third diffusion layer overlapping the first gate insulating film in a plan view is larger than that of the third diffusion layer overlapping the second gate insulating film in a plan view.

5. The silicon carbide semiconductor device according to claim 4, wherein
the width of the third diffusion layer overlapping the first gate insulating film in a plan view is larger than that of the second diffusion layer overlapping the first gate insulating film in a plan view, and
the width of the third diffusion layer overlapping the second gate insulating film in a plan view is not larger than that of the second diffusion layer overlapping the second gate insulating film in a plan view.

6. The silicon carbide semiconductor device according to claim 4, wherein
the first gate insulating film; and the second gate insulating film are formed to be in contact with at least the surface of the second diffusion layer sandwiched between the silicon carbide semiconductor layer; and the fourth diffusion layer and the surface of the third diffusion layer sandwiched between the silicon carbide semiconductor layer and the fourth diffusion layer.

7. The silicon carbide semiconductor device according to claim 6, wherein
the first gate insulating film is formed to be in contact with part of a surface of the fourth diffusion layer,
the second gate insulating film is formed to be in contact with another part of the surface of the fourth diffusion layer, and
the width of the fourth diffusion layer overlapping the first gate insulating film in a plan view is larger than that of the fourth diffusion layer overlapping the second gate insulating film in a plan view.

8. The silicon carbide semiconductor device according to claim 6, wherein
the width of the third diffusion layer sandwiched between the silicon carbide semiconductor layer and the fourth diffusion layer, which overlaps the first gate insulating film in a plan view, is smaller than 1.0 μm.

9. The silicon carbide semiconductor device according claim 4, wherein
the third diffusion layer is formed, extending over the surface layer of the silicon carbide semiconductor layer and the surface layer of the second diffusion layer.

10. A method of manufacturing a silicon carbide semiconductor device, comprising:
forming a second diffusion layer of a second conductivity type by ion implantation partially in a surface layer of a silicon carbide semiconductor layer of a first conductivity type;
forming a resist pattern on a surface of the silicon carbide semiconductor layer;
forming a third diffusion layer of the second conductivity type by ion rotational implantation in at least part of a surface layer of the second diffusion layer which is exposed from the resist pattern; and
forming a fourth diffusion layer of the first conductivity type by ion implantation partially in a surface layer of the third diffusion layer which is exposed from the resist pattern.

11. The method of manufacturing a silicon carbide semiconductor device according to claim 10, wherein
the third diffusion layer of the second conductivity type is formed by the ion rotational implantation at an angle larger than 0 degrees and not larger than 45 degrees.

12. The method of manufacturing a silicon carbide semiconductor device according to claim 10, wherein
the third diffusion layer of the second conductivity type is formed by the ion rotational implantation at an angle not smaller than 30 degrees and not larger than 45 degrees.

13. The method of manufacturing a silicon carbide semiconductor device according to claim 10, wherein
an end portion of the resist pattern has a tapered shape.

14. The method of manufacturing a silicon carbide semiconductor device according to claim 10, wherein
the third diffusion layer is formed to be shallower than the second diffusion layer, and
the fourth diffusion layer is partially formed in the surface layer of the third diffusion layer.

15. The method of manufacturing a silicon carbide semiconductor device according to claim 10, wherein
a first gate insulating film and a second gate insulating film are formed on at least a surface of the second diffusion layer sandwiched between the silicon carbide semiconductor layer and the fourth diffusion layer and a surface of the third diffusion layer sandwiched between the silicon carbide semiconductor layer and the fourth diffusion layer,
a first gate electrode and a second gate electrode are formed on a surface of the first gate insulating film and a surface of the second gate insulating film, and
the width of the third diffusion layer overlapping the first gate insulating film in a plan view is larger than that of the third diffusion layer overlapping the second gate insulating film in a plan view.
